(19) United States
(12) Patent Application Publication
(10) Pub. No.: US 2011/0287177 A1
(43) Pub. Date: Nov. 24, 2011

(54) VACUUM PROCESSING APPARATUS, SUBSTRATE ROTATION APPARATUS, AND DEPOSITION METHOD

(75) Inventors: Satoshi Yamada, Kawasaki-shi (JP); Masaaki Ishida, Kawasaki-shi (JP)

(73) Assignee: CANON ANELVA CORPORATION, Kawasaki-shi (JP)

(21) Appl. No.: 13/099,535

(22) Filed: May 3, 2011

(30) Foreign Application Priority Data
May 19, 2010 (JP) 2010-115162

(51) Int. Cl. C23C 14/50; B05D 5/12

(52) U.S. Cl. 427/127; 118/50

(57) ABSTRACT

An apparatus for rotating a substrate having a center hole, comprises a pickup member configured to hold the substrate by holding an edge of the center hole, and a driving unit configured to drive the pickup member, wherein the driving unit is configured to insert the pickup member into the center hole so as not to bring the pickup member into contact with the substrate, to drive the pickup member upward so that the pickup member holds the edge of the center hole from below, and thereupon to rotate the pickup member so as to rotate the substrate, and in rotating the substrate, the driving unit rotates the pickup member about a rotation axis which is perpendicular to a principal surface of the substrate and passes through the center of the substrate.

### BACKGROUND OF THE INVENTION

1. Field of the Invention

The present invention relates to a deposition method, a substrate rotation apparatus, and a vacuum processing apparatus and, more specifically, to a vacuum processing apparatus, a substrate rotation apparatus, and a deposition method which are suitable for manufacturing a magnetic recording medium formed by sequentially depositing an underlying layer, a magnetic layer, and a protective layer on a substrate made of an insulating material.

2. Description of the Related Art

A magnetic recording medium includes, for example, an underlying layer which is made of NiP and formed on a substrate, a Cr underlying layer deposited on the former underlying layer by sputtering, and a magnetic layer made of Cr or a Co alloy. A protective layer is further deposited on the magnetic layer, for example, a carbon-sputtered layer (see Japanese Patent Laid-Open Nos. 63-26827 and 03-125322).

In the manufacture of a magnetic recording medium, a substrate on which a film is to be deposited is sequentially transported into a plurality of deposition processing chambers which are continuously connected to each other between a load chamber and an unload chamber, thereby performing a process of deposition of each layer such as an underlying layer and a magnetic layer. A transport mechanism capable of transporting a substrate between the deposition processing chambers while holding the substrate on a carrier is used to transport the substrate. The carrier which moves by means of the transport mechanism is formed by attaching a substrate holder, which holds the substrate, onto a slider. The substrate is gripped by leaf spring-like substrate holding grippers attached on the substrate holder.

Note that in the manufacture of a magnetic recording medium using a substrate made of an insulating material such as glass, the sputtering method can be employed to form an underlying layer as well. That is, after a substrate is charged into a vacuum processing chamber, and a metal layer (made of, for example, NiP or Cr) is deposited on the substrate as an underlying layer by DC magnetron sputtering, a magnetic layer and a protective layer can be sequentially deposited. A magnetic layer can be deposited while a bias is applied to the substrate. At this time, a bias can be applied to the substrate via the substrate holding grippers of the substrate holder.

However, when the substrate is held by the substrate holding grippers provided on the substrate holder, it is often the case that an underlying layer with excellent conductivity cannot be deposited on portions shadowed by the substrate holding grippers and therefore the underlying layer and the substrate holding grippers cannot electrically contact each other. In this case, in applying a bias, the electric resistance between the substrate and the substrate holder (substrate holding grippers) is so high and unstable that a desired thin film cannot be formed.

Hence, to solve the above-mentioned problem, Japanese Patent Laid-Open No. 07-243037 discloses a technique in which after an underlying layer is deposited, the substrate held on the substrate holder is rotated to bring the substrate holding grippers into contact with the portions on which the underlying layer is deposited.

In the technique described in Japanese Patent Laid-Open No. 07-243037, while the substrate holding grippers of the substrate holder are temporarily bent to cancel the holding of the substrate on the substrate holder, a holding rod (pickup member) is inserted into the center hole in the substrate to hold it, the holding rod is rotated through a predetermined angle, and thereupon the substrate holding grippers are returned. By performing this operation after an underlying layer is deposited, conduction between the substrate holding grippers and the underlying layer is ensured, thus reliably applying a bias to the substrate. This makes it possible to obtain a magnetic recording medium with a desired film quality.

In a process of manufacturing a magnetic recording medium, the substrate, substrate holder, and the slider are heated by a substrate heating mechanism, chamber baking, and sputtering, so the substrate holder and slider may suffer from thermal expansion. When this occurs, the holding rod may collide with the substrate if the relative position between the center hole and the holding rod changes in inserting the holding rod into the center hole.

In view of this, the inventors of the present invention speculated that the following arrangement is useful. The dimension, in a given direction, of the pickup member which holds the substrate by holding the edge of the center hole in the substrate is set sufficiently smaller than the center hole, the pickup member is inserted into the center hole, and thereupon the pickup member is driven upward to hold the edge of the center hole from below. However, in this arrangement, when the pickup member is rotated using the central axis of the pickup member as its rotation axis, a substrate 109 held by a pickup member 132 performs a swing operation (wiper operation), as shown in FIG. 6. Due to this swing operation, substrate holding becomes unstable, so, for example, the substrate may fall from the substrate holder.

### SUMMARY OF THE INVENTION

The present invention provides a technique advantageous to stably rotate a substrate in an apparatus such as a vacuum processing apparatus.

The first aspect of the present invention provides a vacuum processing apparatus for depositing a conductive layer on a surface of a substrate and thereupon deposits a layer different from the conductive layer, the apparatus comprising: a substrate holder configured to hold the substrate via a conductive substrate holding gripper, and be transported in the vacuum processing apparatus; and a substrate rotation apparatus configured to change a contact position between the substrate holding gripper and the substrate so as to electrically connect the substrate holding gripper and the conductive layer, after the conductive layer is deposited, the substrate rotation apparatus including an arm configured to perform an operation of bending the substrate holding gripper to cancel holding of the substrate by the substrate holder, a pickup member configured to hold the substrate after holding of the substrate by the substrate holding gripper is canceled, and a driving unit configured to drive the pickup member in a direction perpendicular to a principal surface of the substrate held by the substrate holder, a vertical direction, and a rotation direction about an axis parallel to the direction perpendicular to the principal surface, wherein the rotation center of the pickup member and the center of the substrate coincide with each other in rotating the pickup member.

The second aspect of the present invention provides an apparatus for rotating a substrate having a center hole, the apparatus comprising: a pickup member configured to hold the substrate by holding an edge of the center hole; and a driving unit configured to drive the pickup member, wherein the driving unit is configured to insert the pickup member into the center hole so as not to bring the pickup member into contact with the substrate, to drive the pickup member upward so that the pickup member holds the edge of the center hole from below, and thereupon to rotate the pickup member so as to rotate the substrate, and in rotating the substrate, the driving unit rotates the pickup member about a rotation axis which is perpendicular to a principal surface of the substrate and passes through the center of the substrate.

Further features of the present invention will become apparent from the following description of exemplary embodiments with reference to the attached drawings.

### BRIEF DESCRIPTION OF THE DRAWINGS

FIG. 1 is a schematic view of a vacuum processing apparatus according to an embodiment of the present invention;

FIG. 2 is a schematic view of a carrier used for the vacuum processing apparatus according to the embodiment of the present invention;

FIG. 3 is a schematic view of a substrate rotation chamber according to the embodiment of the present invention;

FIGS. 4A and 4B are a perspective view and enlarged view for explaining the pick portion of the substrate rotation apparatus according to the embodiment of the present invention;

FIGS. 5A to 51 are views for explaining the operation of the substrate rotation apparatus according to the embodiment of the present invention; and

FIG. 6 is a view for explaining the wiper operation of a substrate.

### DESCRIPTION OF THE EMBODIMENTS

An embodiment of the present invention will be described below with reference to the accompanying drawings. Note that members, arrangements, and other features to be described hereinafter merely give examples in which the present invention is embodied, and do not limit the present invention, so various modifications and changes can be made without departing from the scope of the present invention, as a matter of course.

Although a substrate rotation apparatus according to the present invention is suitable for, for example, a sputtering deposition apparatus, it is also suitable for a vacuum process in which a bias is applied to a substrate in an apparatus which performs dry etching or other types of vacuum processing. An example in which the present invention is applied to an in-line sputtering deposition apparatus (vacuum processing apparatus S) will be described below.

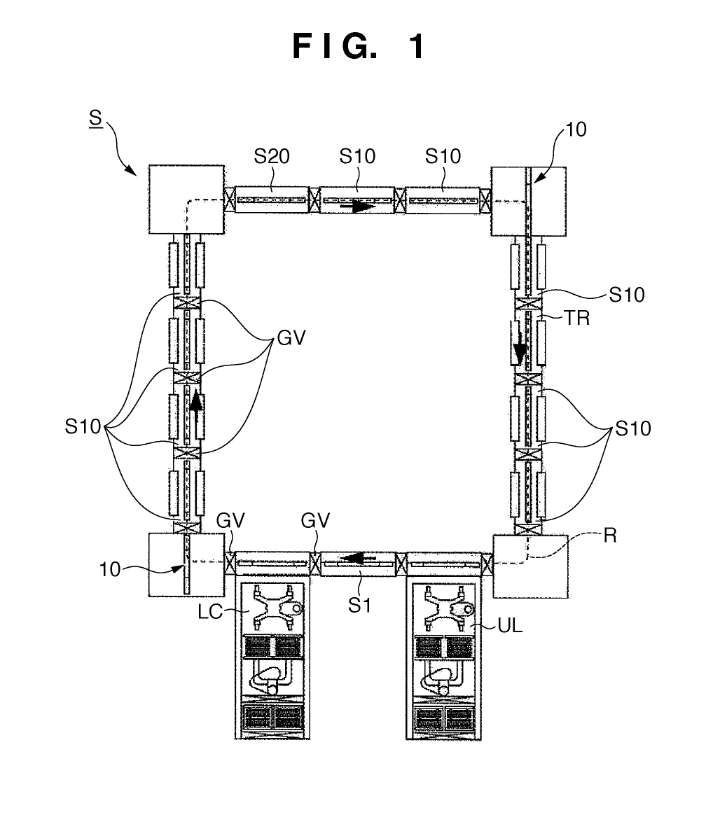

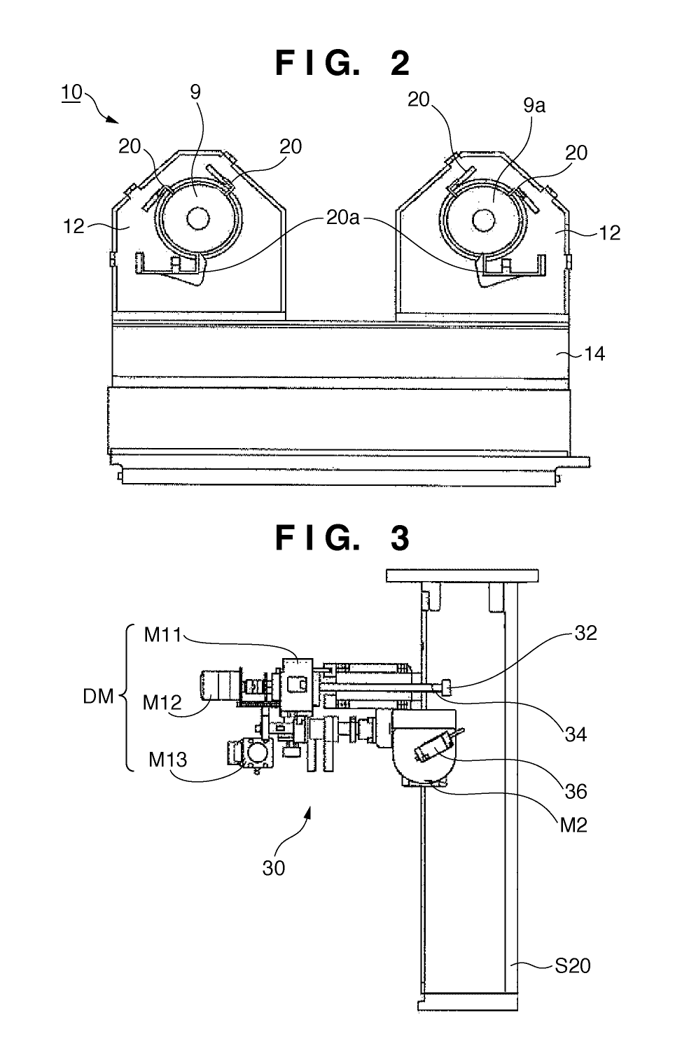

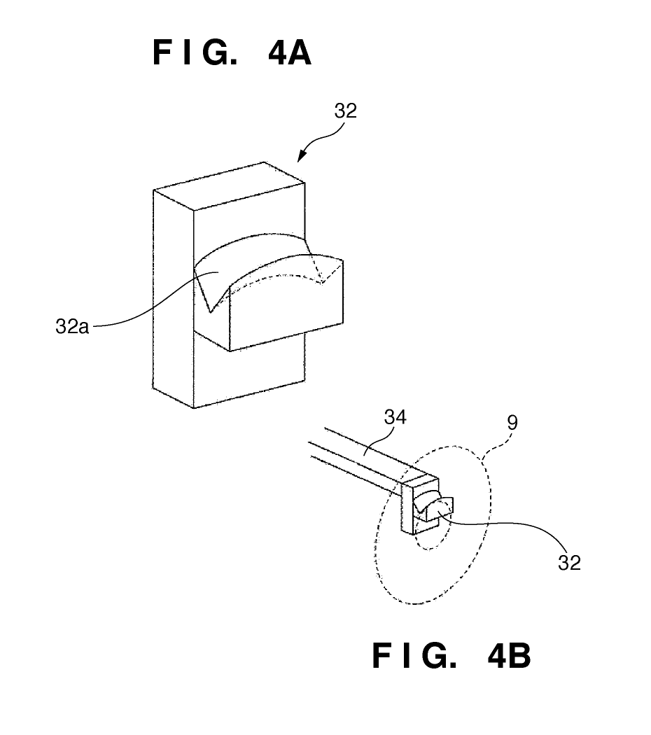

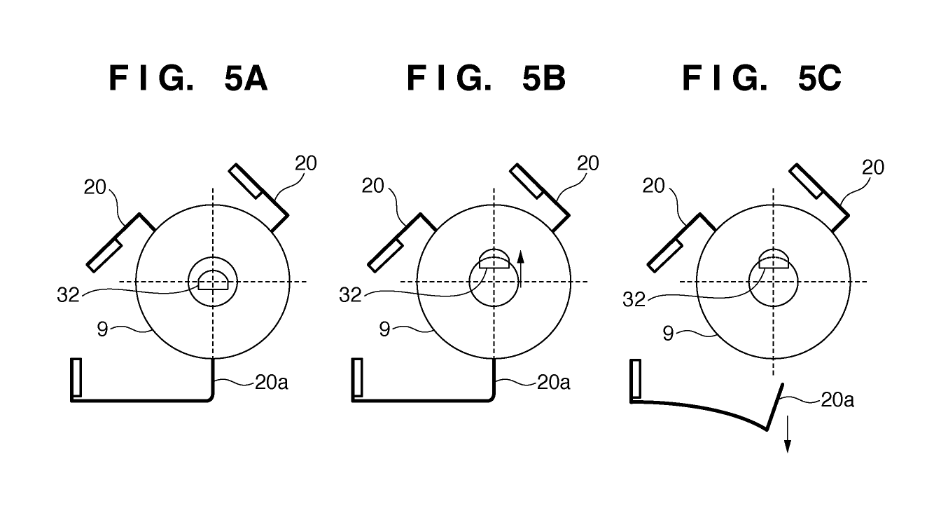

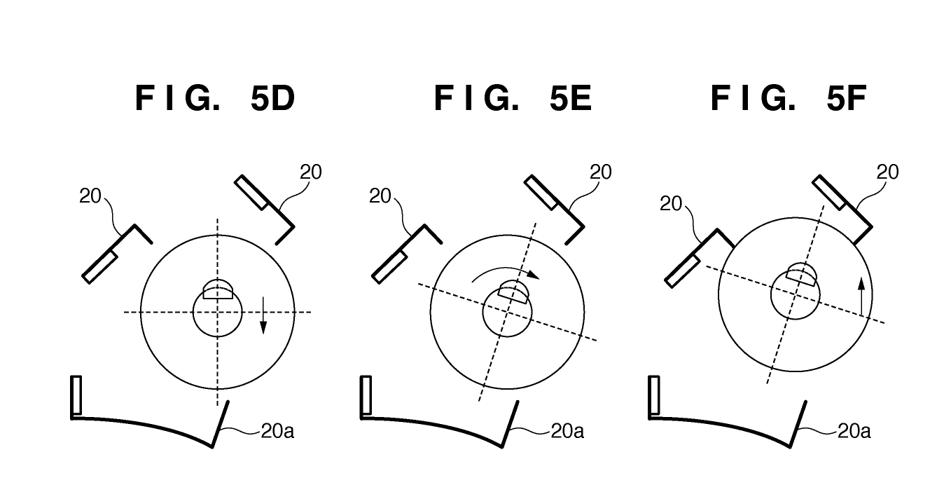

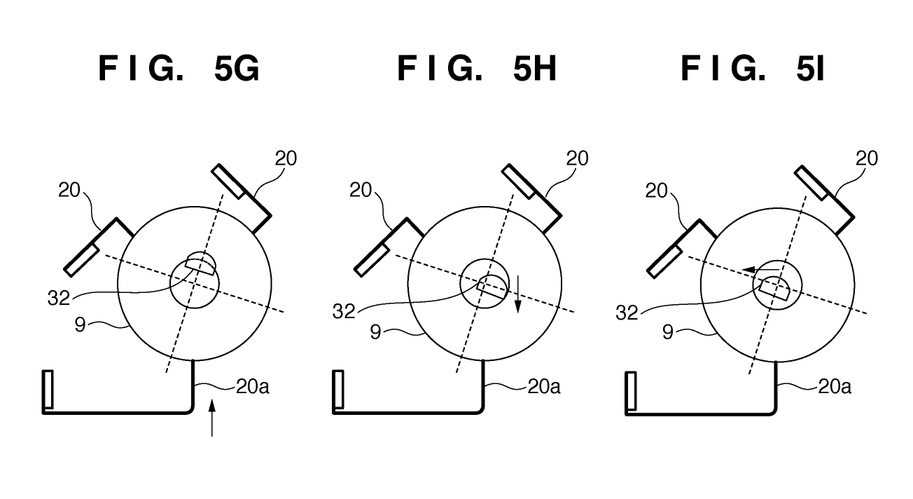

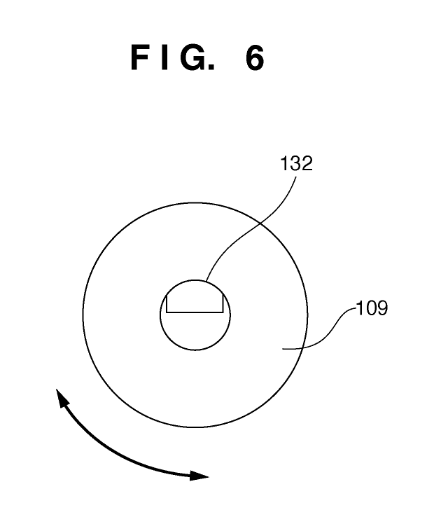

FIGS. 1 to 5A to 5I are views for explaining an embodiment of the present invention, in which FIG. 1 is a schematic view of a vacuum processing apparatus; FIG. 2 is a schematic view of a carrier; FIG. 3 is a schematic view of a substrate rotation chamber; FIGS. 4A and 4B are a perspective view and enlarged view for explaining a pickup member of a substrate rotation apparatus; and FIGS. 5A to 51 are views for explaining the operation of the substrate rotation apparatus. Note that some parts are not shown in these drawings to avoid their complications.

The vacuum processing apparatus S shown in FIG. 1 is an in-line sputtering deposition apparatus, in which a plurality of chambers which function as a load chamber LC, an unload chamber UL, deposition chambers S10, a substrate rotation chamber S20, and other processing chambers are connected to each other in a rectangular shape via gate valves GV. The vacuum processing apparatus S also includes a substrate transport apparatus TR capable of transporting a carrier 10 along a substrate transport path R which runs through the deposition chambers S10.

The substrate transport apparatus TR is a so-called vertical holing type transfer unit, which holds a substrate 9 to assume a vertical attitude with which its principal surface is parallel to the vertical direction. After the substrate 9 is temporarily charged into a cassette in the load chamber LC, it is transferred onto a substrate holder 12 of the carrier 10 by a transfer robot. The substrate 9 is transported along the substrate transport path R while being mounted on the substrate holders 12, and undergoes a predetermined process in each chamber S10.

FIG. 2 is a schematic view showing the carrier 10. The carrier 10 is formed by attaching at least one substrate holder 12 onto a slider 14. A permanent magnet capable of forming a magnetic coupling with a magnetic screw and an electromagnet device which are provided in the substrate transport path R is fixed on the slider 14. The substrate holder 12 is provided with a plurality of (three in this case) substrate holding grippers (substrate holding members) 20 for holding the substrate 9. The substrate holding gripper 20 can be formed from, for example, a bent leaf spring with a given elasticity. Also, the substrate holding gripper 20 is, for example, a metallic member, which is provided while being electrically connected to the substrate holder 12. Note that the lowest one of the three substrate holding grippers 20 attached on each substrate holder 12 is defined as a lower gripper 20a.

The substrate 9 in this embodiment is preferably a disk-like member and is used for a storage medium such as a magnetic disk or an optical disk. However, glass substrates or resin substrates, both with various shapes, can also be used by exchanging the substrate holder 12 attached on the carrier 10.

The deposition chambers S10 are one type of processing chamber which constitutes the vacuum processing apparatus S, and are configured such that a deposition process can be performed on the substrate 9 held by the substrate holder 12 to assume a vertical attitude. The interior of the deposition chamber S10 is provided with at least a cathode on which a target serving as a sputter source can be mounted, and the substrate transport path R along which the substrate 9 is transported, and can be exhausted by a vacuum pump.

The cathode can be attached to the inner side wall of the deposition chamber S10 in order to deposit a film on the substrate 9 held by the substrate transport apparatus TR. By attaching an arbitrary target to the cathode, the target can be disposed to be parallel to the deposition surface of the substrate 9. Also, in the vacuum processing apparatus S according to this embodiment, pluralities of cathodes can be arranged on both sides of the substrate transport path R in order to simultaneously perform deposition processes on the two surfaces of the substrate 9 held by the substrate transport apparatus TR.

The substrate rotation chamber S20 is provided between the deposition chambers S10. The substrate rotation chamber S20 is a chamber provided with a mechanism (substrate rotation apparatus) which rotates the substrate 9, held by the substrate holder 12, so that after an underlying layer is deposited, the substrate holding grippers (substrate holding members) 20 come into contact with the portions on which the underlying layer is deposited. The substrate rotation chamber S20 is provided with the substrate transport apparatus TR (substrate transport path R) to be able to transport the substrate 9 from the deposition chamber S10 in which a preprocess is performed.

In this embodiment, the deposition chamber S10 in which a preprocess is performed is a chamber in which an underlying layer is deposited. An NiP layer or a CoFe alloy layer, for example, can be formed as an underlying layer. Note that a chamber (deposition chamber S10) in which another underlying layer or a magnetic layer is deposited is connected to the substrate rotation chamber S20 on the downstream side in the substrate transport path R.

FIG. 3 is a schematic sectional view showing the substrate rotation chamber S20. The substrate rotation chamber S20 includes the substrate transport path R (not shown) which transports the carrier 10 on which the substrate 9 is mounted, and a substrate rotation apparatus 30 which rotates the substrate 9 mounted on the carrier 10. The substrate rotation apparatus 30 is attached on the outer wall surface of the substrate rotation chamber S20. The substrate rotation apparatus 30 includes, as main constituent elements, a shaft 34 having a pickup member 32 attached at its distal end, three motors M1 which operate the pickup member 32 via the shaft 34, and a control device (not shown) which controls rotation of the motors M1. One substrate rotation apparatus 30 is provided to each substrate holder 12. The dimension of the pickup member 32 in a direction perpendicular to the axial direction of the shaft 34 is smaller than the center hole in the substrate 9 to be held.

An arm 36 for pressing down the substrate holding gripper (lower gripper) 20a which holds the lower portion of the substrate 9 is also provided in the substrate rotation chamber S20. The arm 36 is connected to a driving unit DM including a vacuum motor (stepping motor) M2 provided in the substrate rotation chamber S20, and therefore can be operated by rotating the vacuum motor M2. The arm 36 is a member with a pin-like distal end. Therefore, by operating the arm 36 while the carrier 10 is kept stopped, the lower gripper 20a can be pressed down to cancel holding of the substrate 9.

The shaft 34 is a rod-like member, which is driven by the driving unit DM including four motors M1 (motors M11, M12, M13, and M14) arranged outside the substrate rotation chamber S20 to be able to perform a first-direction operation in a direction to come closer to or go away from the substrate 9, a rotation operation which uses an axis parallel to the central axis of the shaft 34 as its center, a second-direction operation in the direction in which the substrate transport apparatus TR transports the substrate 9, and a third-direction operation in the vertical direction. For example, the motors M11, M12, M13, and M14 (not shown) correspond to the first-direction operation, the rotation operation, the second-direction operation, and the third-direction operation, respectively. Since the motor M14 is placed on the reverse surface of FIG. 3, it is not shown in FIG. 3.

The pickup member 32 is attached at the distal end of the shaft 34 (its end placed in the substrate rotation chamber S20). When the shaft 34 performs an operation (that is, a first-direction operation) in a direction perpendicular to the deposition surface (principal surface) of the substrate 9, the pickup member 32 can be inserted into a center hole 9a in the substrate 9 mounted on the carrier 10 kept stopped.

The pickup member 32 will be described with reference to FIGS. 4A and 4B. FIG. 4A is a perspective view showing the pickup member 32. The pickup member 32 has a holding groove 32a, and can hold the substrate 9 in the holding groove 32a upon coming into contact with the upper portion of the center hole 9a in the substrate 9, as shown in FIG. 4B. Because the center of gravity of the substrate 9 falls within the width of the holding groove 32a in the direction in which the substrate transport apparatus TR transports the substrate 9, the pickup member 32 can stably hold the substrate 9. Note that as the position of the center of gravity of the substrate 9 in the transport direction gets closer to the central position of the holding groove 32a in the transport direction, the wiper operation of the substrate 9 can be suppressed more effectively and efficiently.

The operation of the substrate rotation apparatus 30 will be described with reference to FIGS. 5A to 5I. When the carrier 10 is located outside the substrate rotation chamber S20, the pickup member 32 stands by while being retracted on the side of the substrate rotation apparatus 30 (on its lateral wall side) from the substrate transport path R. The rotation operation of the substrate 9 performed after the carrier 10 is transported into the substrate rotation chamber S20 is as follows. Broken lines in FIGS. 5A to 5I indicate the center of the substrate 9.

FIG. 5A shows the state before substrate rotation while the carrier 10 is kept stopped at a predetermined position in the substrate rotation chamber S20. That is, when the carrier 10 is transported to and stopped at a predetermined position in the substrate rotation chamber S20, the shaft 34 extends to allow the pickup member 32 to be inserted into the center hole 9a in the substrate 9 (first process). The pickup member 32 is driven upward by the driving unit DM so as to come close to the edge of the center hole 9a while the substrate 9 is held by the substrate holding grippers 20 of the substrate holder 12, as shown in FIG. 5B (second process). The pickup member 32 is driven so as to come close to the edge of the center hole 9a or be spaced apart from it by a very small amount.

The lower gripper 20a is bent downward by the arm 36 to cancel holding of the substrate 9 by the substrate holder 12 (substrate holding grippers 20), as shown in FIG. 5C (third process). The lower gripper 20a is pressed down so as to hang over the arm 36. In the state shown in FIG. 5C, the pickup member 32 is desirably kept in contact with the edge of the center hole 9a, so the vertical position of the pickup member 32 may be adjusted so that the pickup member 32 comes into contact with the edge of the center hole 9a in the substrate 9 upon canceling holding of the substrate 9 by the substrate holder 12 (substrate holding grippers 20).

The pickup member 32 is moved downward by the driving unit DM to form a space between the outer periphery of the substrate 9 and the substrate holding grippers 20, and is thereupon rotated using a virtual line, which is perpendicular to the deposition surface (principal surface) of the substrate 9 and passes through the center of the substrate 9, as its rotation axis, as shown in FIGS. 5D and 5E. This rotation is done by driving the shaft 34 using the motors M1 (fourth process). Note that the holding groove 32a in the pickup member 32 is configured to have a frictional force with the edge of the center hole 9a in the substrate 9, that is large enough to rotate the substrate 9.

The pickup member 32 is moved upward by the driving unit DM to hold the substrate 9 using the substrate holding grippers 20, as shown in FIG. 5F. At this time, when the center of gravity of the substrate 9 is set to fall within the holding width (the width of the portion which holds the substrate 9) of the pickup member 32, and a virtual line which is perpendicular to the principal surface of the substrate 9 and passes through the center of the substrate 9 is defined as the rotation axis of the pickup member 32, the substrate 9 can be brought into contact with the two upper substrate holding grippers 20 without requiring a change in substrate position before and after substrate rotation.

The arm 36 is activated to return the lower gripper 20a to the upper position, thereby holding the substrate 9 at three points, that is, by the two substrate holding grippers 20 and the single substrate holding gripper 20a of the substrate holder 12, as shown in FIG. 5G (fifth process). The shaft 34 is moved downward by the driving unit DM to vertically separate the holding groove 32a in the pickup member 32 and the edge of the center hole 9a from each other, as shown in FIG. 5H (sixth process). The pickup member 32 is moved in the direction, in which the substrate transport apparatus TR transports the substrate 9, by the driving unit DM to the position at which the gap between the pickup member 32 and the edge of the center hole 9a in the substrate 9 in the transport direction becomes uniform, as shown in FIG. 5I (seventh process). Thus, a sufficiently wide gap can be ensured between the pickup member 32 and the edge of the center hole 9a in the substrate 9. Lastly, the pickup member 32 is retracted from the substrate transport path R by the driving unit DM to end the substrate rotation operation. Note that the same process as the seventh process can be done before the first process as well.

In this embodiment, the position of the center hole 9a in the substrate 9 is set in advance. That is, a change in position of the center hole 9a due to a fluctuation in substrate holding position, that accompanies thermal expansion of the carrier 10, is set in advance, and the above-mentioned processes are performed by operating the pickup member 32 and shaft 34 using the set coordinates (space position) as its center. However, the above-mentioned processes may be performed while monitoring the position of the substrate 9 by a position sensor such as a CCD camera, as a matter of course.

With the above-mentioned deposition method, a thin film with desired characteristics can be obtained by depositing a plurality of layers on a substrate made of an insulating member. The above-mentioned substrate rotation apparatus can prevent a fall of the substrate 9, that is encountered when the pickup member 32 comes into contact with the substrate 9 during its forward/backward moving operation. This apparatus can also maintain the relative position between the pickup member 32 and the substrate holder 12 regardless of whether the slider 14 and substrate holder 12 suffer from thermal expansion, thereby preventing a fall of the substrate 9. This makes it possible to enhance the reliability in substrate manipulation.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-115162, filed May 19, 2010, which is hereby incorporated by reference herein in its entirety.

What is claimed is:

1. A vacuum processing apparatus for depositing a conductive layer on a surface of a substrate and thereupon deposits a layer different from the conductive layer, the apparatus comprising:
a substrate holder configured to hold the substrate via a conductive substrate holding gripper, and be transported in the vacuum processing apparatus; and
a substrate rotation apparatus configured to change a contact position between the substrate holding gripper and the substrate so as to electrically connect the substrate holding gripper and the conductive layer, after the conductive layer is deposited,
the substrate rotation apparatus including an arm configured to perform an operation of bending the substrate holding gripper to cancel holding of the substrate by the substrate holder,
a pickup member configured to hold the substrate after holding of the substrate by the substrate holding gripper is canceled, and
a driving unit configured to drive the pickup member in a direction perpendicular to a principal surface of the substrate held by the substrate holder, a vertical direction, and a rotation direction about an axis parallel to the direction perpendicular to the principal surface,
wherein the rotation center of the pickup member and the center of the substrate coincide with each other in rotating the pickup member.

2. The apparatus according to claim 1, wherein
a center hole is formed in the substrate, and
the pickup member holds the substrate upon coming into contact with an edge of the center hole.

3. The apparatus according to claim 1, wherein
the driving unit is further configured to drive the pickup member in a direction in which the substrate holder is transported.

4. A method of forming a thin film using a vacuum processing apparatus defined in claim 3, the method comprising the steps of:
moving the pickup member forward to come close to the substrate held on the substrate holder kept stopped at a predetermined position to insert the pickup member into the center hole;
operating the arm to bend the substrate holding gripper to cancel holding of the substrate by the substrate holder and hold the substrate using the pickup member;
rotating the pickup member which holds the substrate;
operating the arm to hold the substrate using the substrate holder again; and
moving the pickup member in a direction in which the substrate is transported.

5. An apparatus for rotating a substrate having a center hole, the apparatus comprising:
a pickup member configured to hold the substrate by holding an edge of the center hole; and
a driving unit configured to drive the pickup member,
wherein the driving unit is configured to insert the pickup member into the center hole so as not to bring the pickup member into contact with the substrate, to drive the pickup member upward so that the pickup member holds the edge of the center hole from below, and thereupon to rotate the pickup member so as to rotate the substrate, and
in rotating the substrate, the driving unit rotates the pickup member about a rotation axis which is perpendicular to a principal surface of the substrate and passes through the center of the substrate.
